(19) United States
(12) Patent Application Publication
(10) Pub. No.: US 2026/0194577 A1
(43) Pub. Date: Jul. 9, 2026

(54) Battery Discharge Diagnosis Apparatus and Operating Method Thereof

(71) Applicant: LG Energy Solution, Ltd., Seoul (KR)

(72) Inventor: Min Young Chae, Daejeon (KR)

(73) Assignee: LG Energy Solution, Ltd., Seoul (KR)

(21) Appl. No.: 19/134,303

(22) PCT Filed: Jul. 4, 2023
(86) PCT No.: PCT/KR2023/009446

§ 371 Date: May 30, 2025

(30) Foreign Application Priority Data
Dec. 9, 2022 (KR) 10-2022-0171810

(51) Int. Cl. G01R 31/36; G01R 31/392

(52) U.S. Cl. CPC G01R 31/3648; G01R 31/392

(57) ABSTRACT

A battery discharge diagnosis apparatus is configured to obtain a voltage of a battery unit and calculate a weighted sum value of a number of times the voltage of the battery unit is sensed in a plurality of different voltage ranges. The battery discharge diagnosis apparatus is further compare the weighted sum value to predetermined threshold values. Based on the comparing, the battery discharge diagnosis apparatus diagnoses a depth of discharge of the battery unit.

### CROSS-REFERENCE TO RELATED APPLICATION

This application is a national phase entry under 35 U.S.C. § 371 of International Application No. PCT/KR2023/009446, filed on Jul. 4, 2023, which claims priority to and the benefit of Korean Patent Application No. 10-2022-0171810 filed in the Korean Intellectual Property Office on Dec. 9, 2022, the entire contents of which are incorporated herein by reference.

### TECHNICAL FIELD

Embodiments disclosed herein relate to a battery discharge diagnosis apparatus and an operating method thereof.

### BACKGROUND ART

Recently, research and development of secondary batteries have been actively performed. Secondary batteries, which are chargeable/dischargeable batteries, may include all of conventional nickel (Ni)/cadmium (Cd) batteries, Ni/metal hydride (MH) batteries, etc., and recent lithium-ion batteries. Among the secondary batteries, a lithium-ion battery has a much higher energy density than those of the conventional Ni/Cd batteries, Ni/MH batteries, etc. Moreover, the lithium-ion battery may be manufactured to be small and lightweight. As such, the lithium-ion battery has been used as a power source of mobile devices, and recently, a use range thereof has been extended to power sources for electric vehicles, attracting attention as next-generation energy storage media.

Furthermore, the secondary battery may be used as a battery pack including a battery module where a plurality of battery cells are connected to one another in series and/or in parallel. The secondary battery may be used as a battery rack, where the battery rack includes a plurality of battery modules and a rack frame receiving the battery modules.

The battery cell, the battery module, the battery pack, or the battery rack may be used in various devices. For example, the batteries may be used not only for mobile devices such as mobile phones, laptop computers, smart phones, smart pads, etc., but also in electric vehicles (EVs), hybrid electric vehicles (HEVs), plug-in hybrid electric vehicles (PHEVs) driven with electricity, large-volume energy storage systems (ESS), etc.

### SUMMARY

### Technical Problem

Recently, discharge of a vehicle AUX battery frequently occurs due to diversified functions, driver's negligence, an influence of an external environment, etc. Discharge of the vehicle AUX battery may accelerate lifetime degradation due to battery deterioration or cause the electric vehicle not to start, and thus needs to be continuously managed.

In a conventional battery system, when the battery of the parked vehicle is discharged, management for preventing the same is not performed. The battery state of the vehicle and whether the vehicle is discharged may not be known until the driver directly starts the vehicle.

Embodiments disclosed herein aim to provide a battery discharge diagnosis apparatus and an operating method thereof in which a depth of discharge of a battery unit may be diagnosed through a weighted sum value calculated based on a voltage of the battery unit and a plurality of voltage ranges, thereby sensing discharge of the battery unit.

Technical problems of the embodiments disclosed herein are not limited to the above-described technical problems, and other unmentioned technical problems would be clearly understood by one of ordinary skill in the art from the following description.

### Technical Solution

A battery discharge diagnosis apparatus according to an embodiment disclosed herein includes memory storing instructions and one or more processors configured to execute the instructions to obtain a voltage of a battery unit, calculate a weighted sum value of a number of times the voltage of the battery unit is sensed in a plurality of different voltage ranges, and diagnose a depth of discharge of the battery unit by comparing the weighted sum value with at least one threshold value.

In the battery discharge diagnosis apparatus, the one or more processors are further configured to calculate the weighted sum value by summing products of the number of times the voltage of the battery unit is sensed in the plurality of different voltage ranges and a plurality of weight values corresponding to the plurality of voltage ranges.

In the battery discharge diagnosis apparatus, the plurality of weight values includes a first weight value corresponding to a voltage range, and the one or more processors are further configured to set the first weight value corresponding to the voltage range to be lower for a higher upper limit of the voltage range.

In the battery discharge diagnosis apparatus, the one or more processors are further configured to obtain first voltage values of a plurality of new battery units having use periods being less than or equal to a first reference period and second voltage values of a plurality of old battery units having use periods being greater than a second reference period, and determine the plurality of voltage ranges based on the first voltage values and the second voltage values.

In the battery discharge diagnosis apparatus, the one or more processors are further configured to determine a first voltage range having a maximum value of the first voltage values as an upper limit and a minimum value of the first voltage values as a lower limit, determine a second voltage range having a maximum value of the second voltage values as an upper limit and a minimum value of the second voltage values as a lower limit, determine a target voltage range by excluding the first voltage range from the second voltage range, and determine the plurality of voltage ranges in the target voltage range.

In the battery discharge diagnosis apparatus, the one or more processors are further configured to determine the plurality of voltage ranges based on a distribution of the second voltage values in the target voltage range.

In the battery discharge diagnosis apparatus, the one or more processors are further configured to obtain a number of times the battery unit is charged by a second battery unit disposed in an electronic device when the electronic device is in a powered-off state, and correct the depth of discharge based on the number of times the battery unit is charged by the second battery unit.

In the battery discharge diagnosis apparatus, the one or more processors are further configured to identify a time for which a voltage of the battery unit is maintained at a designated voltage or less and correct the depth of discharge based on the identified time.

A method of diagnosing battery discharge according to an embodiment disclosed herein includes obtaining a voltage of a battery unit, calculating a weighted sum value of a number of times the voltage of the battery unit is sensed in a plurality of different voltage ranges, and diagnosing a depth of discharge of the battery unit by comparing the weighted sum value with at least one threshold value.

In the method, calculating the weighted sum value comprises determining a sum of products of the number of times the voltage of the battery unit is sensed in the plurality of different voltage ranges and a plurality of weight values corresponding to the plurality of voltage ranges.

In the method, the plurality of weight values includes a first weight value corresponding to a voltage range, wherein the first weight value corresponding to the voltage range is set to be lower for a higher upper limit of the voltage range.

The method further comprises obtaining first voltage values of a plurality of new battery units having use periods being less than or equal to a first reference period and second voltage values of a plurality of old battery units having use periods being greater than a second reference period and determining the plurality of voltage ranges based on the first voltage values and the second voltage values.

In the method, determining the plurality of voltage ranges may include determining a first voltage range having a maximum value of the first voltage values as an upper limit and a minimum value of the first voltage values as a lower limit, determining a second voltage range having a maximum value of the second voltage values as an upper limit and a minimum value of the second voltage values as a lower limit, determining a target voltage range by excluding the first voltage range from the second voltage range, and determining the plurality of voltage ranges in the target voltage range.

In the method, determining the plurality of voltage ranges may include determining the plurality of voltage ranges based on a distribution of the second voltage values in the target voltage range.

The method further comprises obtaining a number of times the battery unit is charged by a second battery unit disposed in an electronic device when the electronic device is in a powered-off state and correcting the depth of discharge based on the number of times the battery unit is charged by the second battery unit.

### Advantageous Effects

The battery discharge diagnosis apparatus and the operating method thereof according to various embodiments disclosed herein may sense discharge of a battery unit, thereby preventing a situation where a vehicle fails to start due to the discharged battery.

The effects of the battery discharge diagnosis apparatus and the operating method thereof according to the disclosure of the present document are not limited to the effects mentioned above, and other effects not mentioned will be clearly understood by those of ordinary skill in the art according to the disclosure of the present document.

Moreover, various effects recognized directly or indirectly from the disclosure may be provided.

### BRIEF DESCRIPTION OF THE DRAWINGS

FIG. 1 is a block diagram of a battery discharge diagnosis apparatus according to an embodiment.

FIG. 2 is a graph showing a voltage of a battery unit, obtained by a battery discharge diagnosis apparatus according to an embodiment.

FIG. 3 is a graph showing an example where a battery discharge diagnosis apparatus according to an embodiment determines a target voltage range.

FIG. 4 is a graph showing an example where a battery discharge diagnosis apparatus according to an embodiment determines a plurality of voltage ranges.

FIG. 5 is a graph showing an example where a battery discharge diagnosis apparatus according to an embodiment calculates a weighted sum value.

FIG. 6 is a flowchart illustrating an example method of using a battery discharge diagnosis apparatus according to an embodiment.

FIG. 7 is a flowchart illustrating an example method of using a battery discharge diagnosis apparatus according to an embodiment.

### DETAILED DESCRIPTION

Hereinafter, various embodiments of the present disclosure will be disclosed with reference to the accompanying drawings. However, the description is not intended to limit the present disclosure to particular embodiments, and it should be construed as including various modifications, equivalents, and/or alternatives according to the embodiments of the present disclosure.

It should be appreciated that various embodiments of the present document and the terms used therein are not intended to limit the technological features set forth herein to particular embodiments and include various changes, equivalents, or replacements for a corresponding embodiment. Referring to the description of the drawings, similar reference numerals may be used to refer to similar or related elements. It is to be understood that a singular form of a noun corresponding to an item may include one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. Such terms as “1^{st}”, “2^{nd},” “first”, “second”, “A”, “B”, “(a)”, or “(b)” may be used to simply distinguish a corresponding component from another, and does not limit the components in other aspect (e.g., importance or order), unless mentioned otherwise.

Herein, it is to be understood that when an element (e.g., a first element) is referred to, with or without the term “operatively” or “communicatively”, as “connected with”, “coupled with”, or “linked with”, or “coupled to” or “connected to” to another element (e.g., a second element), it means that the element may be connected with the other element directly (e.g., wired), wirelessly, or via a third element.

A method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store, or between two user devices directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically. One or more of the operations may be executed in a different order or omitted, or one or more other operations may be added.

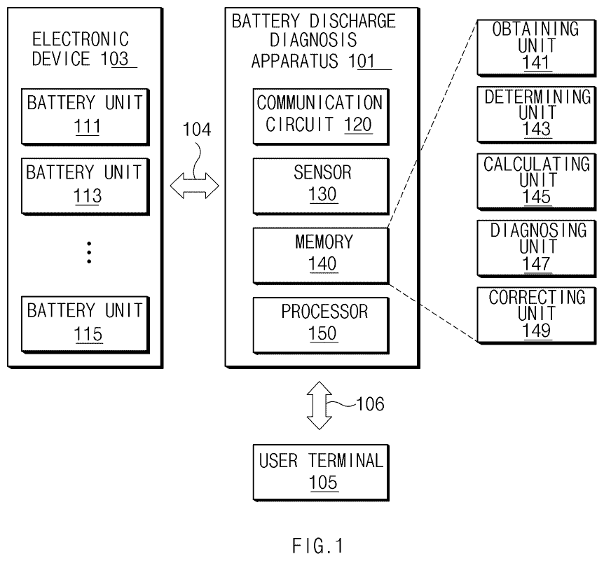

FIG. 1 is a block diagram of a battery discharge diagnosis apparatus according to an embodiment.

Referring to FIG. 1, a battery discharge diagnosis apparatus 101 may be wired and/or wirelessly connected to an electronic device 103 and a user terminal 105.

Connection 104 between the battery discharge diagnosis apparatus 101 and the electronic device 103 may be a communication connection through a wired and/or wireless network. The wired network may be based on a local area network (LAN) communication or a power-line communication. The wireless network may be based on a short-range communication network (e.g., Bluetooth, Wireless Fidelity (WiFi), Infrared Data Association (IrDA)) or a remote-range communication network (e.g., a cellular network, a 4^{th}-Generation (4G) network, a 5^{th} Generation (5G) network).

According to another embodiment, the connection 104 between the battery discharge diagnosis apparatus 101 and the electronic device 103 may be a connection using a device-to-device communication scheme (e.g., a bus, a general-purpose input and output (GPIO), a serial peripheral interface (SPI), or a mobile industry processor interface (MIPI)).

Connection 106 between the battery discharge diagnosis apparatus 101 and the user terminal 105 may be a communication connection through a wired and/or wireless network.

The electronic device 103 may be a mobile device (e.g., a mobile phone, a laptop computer, a smart phone, a smart pad), an electric vehicle (e.g., an electric vehicle (EV), a hybrid EV (HEV), a plug-in HEV (PHEV), a fuel cell EV (FCEV)), an energy storage system (ESS), or a battery swapping system (BSS).

The electronic device 103 may include one or more battery units 111, 113, and 115. For example, when the electronic device 103 is an electric vehicle, the one or more battery units 111, 113, and 115 may be vehicle AUX batteries. Herein, each of the one or more battery units 111, 113, and 115 may be a battery cell, a battery module, a battery pack, or a battery rack.

The user terminal 105 may be a mobile device (e.g., a mobile phone, a laptop computer, a smart phone, a smart pad), or a personal computer (PC).

The battery discharge diagnosis apparatus 101 may include a communication circuit 120, a sensor 130, a memory 140, and a processor 150. The battery discharge diagnosis apparatus 101 shown in FIG. 1 may further include at least one component (e.g., a display, an input device, or an output device) in addition to the components shown in FIG. 1.

The communication circuit 120 may establish a wired communication channel and/or a wireless communication channel between the battery discharge diagnosis apparatus 101 and the electronic device 103 and/or the user terminal 105. The communication circuit 120 may transmit and receive data to and from the electronic device 103 and/or the user terminal 105 through the established communication channel.

The communication circuit 120 may establish a wired communication channel and/or a wireless communication channel between the battery discharge diagnosis apparatus 101 and an external server. The communication circuit 120 may transmit and receive data to and from the external server through the established communication channel.

The sensor 130 may obtain values related to states of the battery units 111, 113, and 115 of the electronic device 103. The values related to the states may indicate one or more values of voltages, currents, resistances, states of charge (SoC), states of health (SoH), or temperatures of the battery units 111, 113, and 115, or combinations thereof. Hereinbelow, the value related to the state may be referred to as a ‘state value’.

The memory 140 may include a volatile and/or a nonvolatile memory.

The memory 140 may store data used by at least one component (e.g., the processor 150) of the battery discharge diagnosis apparatus 101. For example, the data may include software (or instructions related thereto), input data, or output data. The instructions, when executed by the processor 150, may cause the battery discharge diagnosis apparatus 101 to perform operations defined by the instructions.

The memory 140 may include one or more processors (e.g., an obtaining unit 141, a determining unit 143, a calculating unit 145, a diagnosing unit 147, and a correcting unit 149) that are configured to perform the operations defined by the instructions.

The processor 150 may include at least one of a central processing unit, an application processor, a graphic processing unit, a neural processing unit (NPU), an image signal processor, a sensor hub processor, or a communication processor.

The processor 150 may use one or more different processors within memory 140 (e.g., the obtaining unit 141, the determining unit 143, the calculating unit 145, the diagnosing unit 147, and the correcting unit 149) to control at least one other component (e.g., a hardware or software component) of the battery discharge diagnosis apparatus 101 connected to the processor 150 and to perform various data processing or operations.

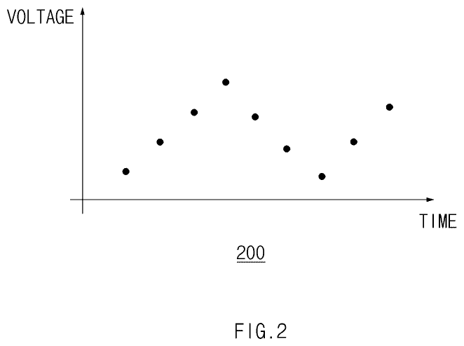

Hereinbelow, referring to FIGS. 2 to 5, a description will be made of a method, performed by the battery discharge diagnosis apparatus 101, of diagnosing depths of discharge of the battery units 111, 113, and 115 using different processors within memory 140, such as the obtaining unit 141, the determining unit 143, the calculating unit 145, the diagnosing unit 147, and/or the correcting unit 149.

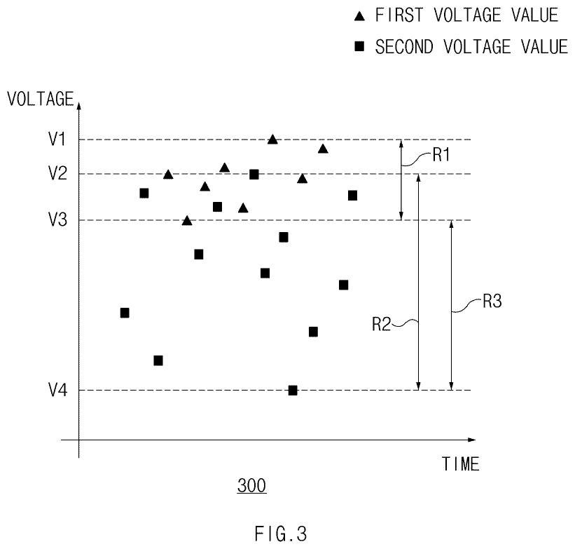

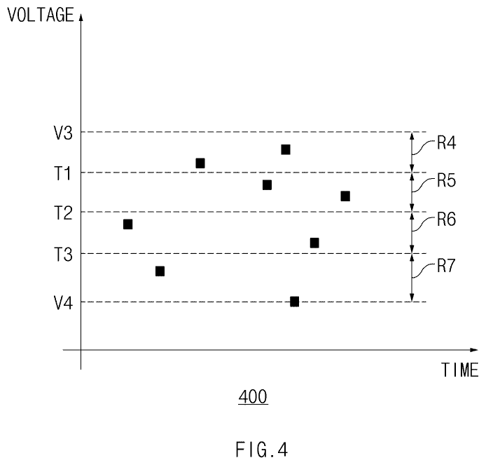

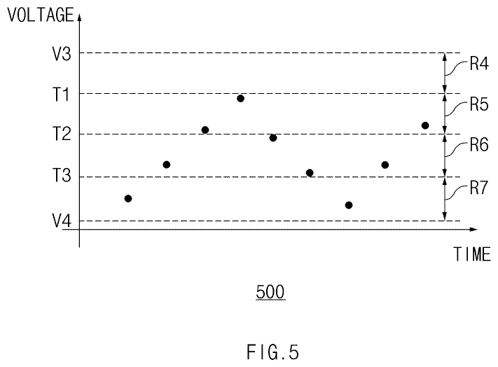

FIG. 2 is a graph showing a voltage of a battery unit, obtained by a battery discharge diagnosis apparatus. FIG. 3 is a graph showing an example where a battery discharge diagnosis apparatus determines a target voltage range. FIG. 4 is a graph showing an example where a battery discharge diagnosis apparatus determines a plurality of voltage ranges. FIG. 5 is a graph showing an example where a battery discharge diagnosis apparatus calculates a weighted sum value. FIGS. 2, 3, 4, and 5 will be described using the components of FIG. 1.

The obtaining unit 141 may obtain a voltage of the battery unit 111, 113, or 115. The obtaining unit 141 may obtain a voltage profile indicating a voltage value of the battery unit 111, 113, or 115 with respect to time.

The obtaining unit 141 may obtain the voltage of the battery unit 111, 113, or 115 through the electronic device 103 connected through a wired and/or wireless network.

Referring to FIG. 2, graph 200 indicates a voltage value of the battery unit 111, 113, or 115 over time. The obtaining unit 141 may discretely obtain the voltage of the battery unit 111, 113, or 115, like the graph 200.

The obtaining unit 141 may obtain first voltage values of a plurality of new battery units having use periods that are less than or equal to a first reference period and second voltage values of a plurality of old battery units having use periods that are greater than a second reference period. Herein, the plurality of new battery units, the plurality of old battery units, and the plurality of battery units 111, 113, and 115 of the electronic device 103 may be battery units of the same model. The first reference period and the second reference period may be equal to or different from each other.

The obtaining unit 141 may obtain the first voltage values and the second voltage values through the external server connected via a wired and/or wireless network.

Referring to FIG. 3, graph 300 depicts the first voltage values and the second voltage values with respect to the obtained time. The obtaining unit 141 may discretely obtain the first voltage values and the second voltage values, like the graph 300.

The obtaining unit 141 may obtain the number of times the battery unit 111, 113, or 115 is charged by another battery unit disposed in the electronic device 103 when the electronic device 103 is in a powered-off state. Herein, the other battery unit may be a battery unit separate from the at least one battery unit 111, 113, and 115 shown in FIG. 1. For example, the other battery unit may include a high-voltage and/or a low-voltage battery. The obtaining unit 141 may obtain the number of times the battery unit 111, 113, or 115 is charged by another battery unit disposed in the electronic device 103 through the electronic device 103 connected through a wire and/or wireless network, when the electronic device 103 is in the powered-off state.

The determining unit 143 may determine a plurality of different voltage ranges. The determining unit 143 may determine the plurality of voltage ranges based on the first voltage values and the second voltage values obtained by the obtaining unit 141.

For example, referring to FIG. 3, the determining unit 143 may determine a first voltage range R1 having a maximum value V1 of the first voltage values as an upper limit and a minimum value V3 of the first voltage values as a lower limit. The determining unit 143 may also determine a second voltage range R2 having a maximum value V2 of the second voltage values as an upper limit and a minimum value V4 of the second voltage values as a lower limit. The determining unit 143 may determine a target voltage range R3 by excluding the first voltage range R1 from the second voltage range R2.

The determining unit 143 may determine a plurality of voltage ranges in the target voltage range R3. The determining unit 143 may determine th plurality of voltage ranges based on a distribution of the second voltage values in the target voltage range R3.

The determining unit 143 may determine the plurality of voltage ranges, each including a designated number of second voltage values in the target voltage range. For example, referring to FIG. 4. the determining unit 143 may determine a plurality of voltage ranges R4, R5, R6, and R7, each including two second voltage values, in the target voltage range. While it is shown in FIG. 4 that each of the plurality of voltage ranges R4, R5, R6, and R7 includes two second voltage values, each voltage range of the plurality of voltage ranges may include more or fewer than two second voltage values.

The calculating unit 145 may calculate a weighted sum value of the number of times the voltage of the battery unit 111, 113, or 115 is sensed in the plurality of voltage ranges. The plurality of voltage ranges may be stored in the memory 140 or determined by the determining unit 143.

The calculating unit 145 may calculate a weighted sum value by summing products of the number of times and a plurality of weight values corresponding to the plurality of voltage ranges.

For example, according to graph 500 of FIG. 5, the calculating unit 145 may calculate, as a first multiplication value, a product of 0 based on multiplying a weight value of 0 corresponding to the voltage range R4 (a voltage range being at least T1 but less than V3) and the number of times the voltage of the battery unit 111, 113, or 115 is sensed in the voltage range R4 being 0. The calculating unit 145 may calculate, as a second multiplication value, a product of 3 based on a weight value of 1 corresponding to the voltage range R5 (a voltage range being at least T2 but less than T1) and the number of times the voltage of the battery unit 111, 113, or 115 is sensed in the voltage range R5 being 3. The calculating unit 145 may calculate, as a third multiplication value, a product of 8 based on a weight value of 2 corresponding to the voltage range R6 (a voltage range being at least T3 but less than T2) and the number of times the voltage of the battery unit 111, 113, or 115 is sensed in the voltage range R6 being 4. The calculating unit 145 may calculate, as a fourth multiplication value, a product of 8 based on a weight value of 4 corresponding to the voltage range R7 (a voltage range being at least V4 but less than T3) and the number of times the voltage of the battery unit 111, 113, or 115 is sensed in the voltage range R7 being 2. The calculating unit 145 may calculate, as the weighted sum value, a sum value of 19 based on adding the first multiplication value, the second multiplication value, the third multiplication value, and the fourth multiplication value.

The calculating unit 145 may set a weight value corresponding to the voltage range to be lower for a higher upper limit of the voltage range. For example, referring to the graph 500 of FIG. 5, the calculating unit 145 may set a weight value corresponding to the voltage range R4 having the highest upper limit to be lowest. The calculating unit 145 may set a weight value corresponding to the voltage range R5 having the second highest upper limit to be lower than weight values corresponding to the voltage ranges R6 and R7. The calculating unit 145 may set a weight value corresponding to the voltage range R6 having the third highest upper limit to be lower than the weight value corresponding to the voltage range R7.

The diagnosing unit 147 may diagnose a depth of discharge of the battery unit 111, 113, or 115 by comparing the weighted sum value with at least one threshold value. For example, the diagnosing unit 147 may diagnose the battery unit 111, 113, or 115 as being in a discharge state when the weighted sum value is greater than or equal to a first threshold value. The diagnosing unit 147 may diagnose the battery unit 111, 113, or 115 as being in a discharge-risk state when the weighted sum value is greater than or equal to a second threshold value less than the first threshold value, but is less than the first threshold value.

The correcting unit 149 may additionally correct the depth of discharge diagnosed by the diagnosing unit 147 based on the number of times the battery unit 111, 113, or 115 is charged by another battery unit disposed in the electronic device 103 when the electronic device 103 is in the powered-off state.

The electronic device 103 may activate a battery saver function that charges the battery unit 111, 113, or 115 by using power stored in the other battery units to prevent the battery unit 111, 113, or 115 from being discharged when the electronic device 103 is in the powered-off state. This battery saver function may be more frequently activated for a higher degree of deterioration. That is, a risk of discharge may increase as the number of times the battery unit 111, 113, or 115 activates the battery saver function. In this regard, the correcting unit 149 may additionally correct the depth of discharge of the battery unit 111, 113, or 115 based on the number of times the battery saver function is activated.

The correcting unit 149 may identify a time for which the voltage of the battery unit 111, 113, or 115 is maintained as a designated voltage or less. The correcting unit 149 may additionally correct the depth of discharge diagnosed by the diagnosing unit 147 based on the identified time. For example, the correcting unit 149 may correct the depth of discharge based on determining that the risk of discharge of the battery unit 111, 113, or 115 is high for a longer time for which the voltage of the battery unit 111, 113, or 115 is maintained as the designated voltage or less. Herein, the designated voltage may be set according to specifications of the battery unit 111, 113, or 115.

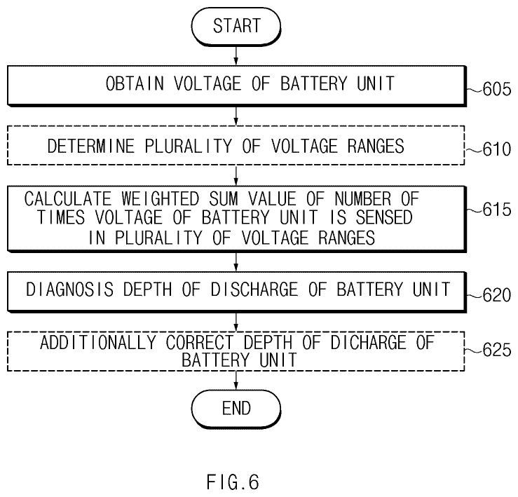

FIG. 6 is a flowchart illustrating an example method of using a battery discharge diagnosis apparatus according to an embodiment. FIG. 6 will be described using components of FIG. 1.

The embodiment shown in FIG. 6 may be an example, and an order of operations according to various embodiments of the present disclosure may be different from that shown in FIG. 6. Some of the operations shown in FIG. 6 may be omitted, the order of the operations may be changed, or the operations may be merged. For example, in FIG. 6, operation 610 and/or operation 625 may be omitted.

Referring to FIG. 6, in operation 605, the battery discharge diagnosis apparatus 101 may obtain a voltage of the battery unit 111, 113, or 115. The battery discharge diagnosis apparatus 101 may obtain a voltage profile indicating a voltage value of the battery unit 111, 113, or 115 over time. The battery discharge diagnosis apparatus 101 may discretely obtain a voltage of the battery unit 111, 113, or 115.

In operation 610, the battery discharge diagnosis apparatus 101 may determine a plurality of different voltage ranges. The battery discharge diagnosis apparatus 101 may determine the plurality of voltage values based on the first voltage values of the plurality of new battery units having use periods being less than or equal to the first reference period and the second voltage values of the plurality of old battery units having use periods being greater than the second reference period.

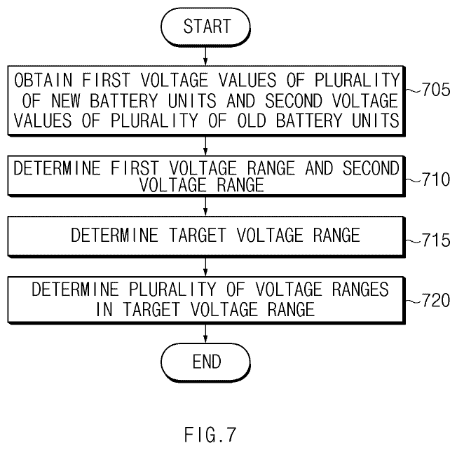

Operation 610, performed by the battery discharge diagnosis apparatus 101, of determining the plurality of different voltage ranges will be described in detail with reference to FIG. 7.

In operation 615, the battery discharge diagnosis apparatus 101 may calculate a weighted sum value of the number of times the voltage of the battery unit 111, 113, or 115 is sensed in the plurality of voltage ranges. Herein, the plurality of voltage ranges may be stored in the memory 140 or determined in operation 610.

The battery discharge diagnosis apparatus 101 may calculate a weighted sum value by summing products of the number of times the voltage of the battery unit 111, 113, or 115 is sensed in the plurality of voltage ranges and a plurality of weight values corresponding to the plurality of voltage ranges. The battery discharge diagnosis apparatus 101 may set a weight value corresponding to the voltage range to be lower for a higher upper limit of the voltage range.

In operation 620, the battery discharge diagnosis apparatus 101 may diagnose a depth of discharge of the battery unit 111, 113, or 115 by comparing the weighted sum value with at least one threshold value. For example, the battery discharge diagnosis apparatus 101 may diagnose the battery unit 111, 113, or 115 as being in a discharge state when the weighted sum value is greater than or equal to a first threshold value. The battery discharge diagnosis apparatus 101 may diagnose the battery unit 111, 113, or 115 as being in a discharge-risk state when the weighted sum value is greater than or equal to a second threshold value but is less than the first threshold value, where the second threshold value is also less than the first threshold value.

In operation 625, the battery discharge diagnosis apparatus 101 may correct the depth of discharge of the battery unit 111, 113, or 115.

The battery discharge diagnosis apparatus 101 may additionally correct the depth of discharge diagnosed in operation 620 based on the number of times the battery unit 111, 113, or 115 is charged by another battery unit disposed in the electronic device 103 when the electronic device 103 is in the powered-off state.

The battery discharge diagnosis apparatus 101 may identify a time for which the voltage of the battery unit 111, 113, or 115 is maintained at a designated voltage or less. The battery discharge diagnosis apparatus 101 may correct the depth of discharge diagnosed in operation 620, based on the identified time. For example, the battery discharge diagnosis apparatus 101 may correct the depth of discharge based on determining the risk of discharge of the battery unit 111, 113, or 115 is high for a longer time for which the voltage of the battery unit 111, 113, or 115 is maintained at the designated voltage or less. Herein, the designated voltage may be set according to specifications of the battery unit 111, 113, or 115.

FIG. 7 is a flowchart illustrating an example method of using a battery discharge diagnosis apparatus according to an embodiment. FIG. 7 will be described using components of FIG. 1.

The embodiment shown in FIG. 7 may be an example and an order of operations according to various embodiments of the present disclosure may be different from that shown in FIG. 7. Some operations shown in FIG. 7 may be omitted, the order of the operations may be changed, or the operations may be merged.

Referring to FIG. 7, in operation 705, the battery discharge diagnosis apparatus 101 may obtain the first voltage values of the plurality of new battery units and the second voltage values of the plurality of old battery units. Herein, the use periods of the plurality of new battery units may be the first reference period or less, and the use periods of the plurality of old battery units may exceed the second reference period. The plurality of new battery units, the plurality of old battery units, and the plurality of battery units 111, 113, and 115 of the electronic device 103 may be battery units of the same model. The first reference period and the second reference period may be equal to or different from each other.

The battery discharge diagnosis apparatus 101 may discretely obtain the first voltage values and the second voltage values.

In operation 710, the battery discharge diagnosis apparatus 101 may determine the first voltage range and the second voltage range.

The battery discharge diagnosis apparatus 101 may determine the first voltage range having the maximum value of the first voltage values obtained in operation 705 as an upper limit and the minimum value of the first voltage values as a lower limit. The battery discharge diagnosis apparatus 101 may determine the second voltage range having the maximum value of the second voltage values as an upper limit and the minimum value of the second voltage values as a lower limit.

In operation 715, the battery discharge diagnosis apparatus 101 may determine a target voltage range. The battery discharge diagnosis apparatus 101 may determine the target voltage range by excluding the first voltage range from the second voltage range.

In operation 720, the battery discharge diagnosis apparatus 101 may determine the plurality of voltage ranges in the target voltage range determined in operation 715.

The battery discharge diagnosis apparatus 101 may determine the plurality of voltage ranges based on a distribution of the second voltage values in the target voltage range. The battery discharge diagnosis apparatus 101 may determine the plurality of voltage ranges, each including a designated number of second voltage values in the target voltage range.

Terms such as “include”, “constitute” or “have” described above may mean that the corresponding component may be inherent unless otherwise stated, and thus should be construed as further including other components rather than excluding other components. All terms including technical or scientific terms have the same meanings as those generally understood by those of ordinary skill in the art to which the embodiments disclosed herein pertain, unless defined otherwise. The terms used generally like terms defined in dictionaries should be interpreted as having meanings that are the same as the contextual meanings of the relevant technology and should not be interpreted as having ideal or excessively formal meanings unless they are clearly defined in the present document.

1. A battery discharge diagnosis apparatus comprising:
memory storing instructions; and
one or more processors configured to execute the instructions to:
obtain a voltage of a battery unit;
calculate a weighted sum value of a number of times the voltage of the battery unit is sensed in a plurality of different voltage ranges; and
diagnose a depth of discharge of the battery unit by comparing the weighted sum value with at least one threshold value.

2. The battery discharge diagnosis apparatus of claim 1, wherein the one or more processors are further configured to calculate the weighted sum value by summing products of the number of times the voltage of the battery unit is sensed in the plurality of different voltage ranges and a plurality of weight values corresponding to the plurality of voltage ranges.

3. The battery discharge diagnosis apparatus of claim 2,
wherein the plurality of weight values includes a first weight value corresponding to a voltage range; and
wherein the one or more processors are further configured to set the first weight value corresponding to the voltage range to be lower for a higher upper limit of the voltage range.

4. The battery discharge diagnosis apparatus of claim 1, wherein the one or more processors are further configured to:
obtain first voltage values of a plurality of new battery units having use periods being less than or equal to a first reference period and second voltage values of a plurality of old battery units having use periods being greater than a second reference period; and
determine the plurality of voltage ranges based on the first voltage values and the second voltage values.

5. The battery discharge diagnosis apparatus of claim 4, wherein the one or more processors are further configured to:
determine a first voltage range having a maximum value of the first voltage values as an upper limit and a minimum value of the first voltage values as a lower limit;
determine a second voltage range having a maximum value of the second voltage values as an upper limit and a minimum value of the second voltage values as a lower limit;
determine a target voltage range by excluding the first voltage range from the second voltage range; and
determine the plurality of voltage ranges in the target voltage range.

6. The battery discharge diagnosis apparatus of claim 5, wherein the one or more processors are further configured to determine the plurality of voltage ranges based on a distribution of the second voltage values in the target voltage range.

7. The battery discharge diagnosis apparatus of claim 1, wherein the one or more processors are further configured to obtain a number of times the battery unit is charged by a second battery unit disposed in an electronic device when the electronic device is in a powered-off state; and
correct the depth of discharge based on the number of times the battery unit is charged by the second battery unit.

8. The battery discharge diagnosis apparatus of claim 1, wherein the one or more processors are further configured to identify a time for which a voltage of the battery unit is maintained at a designated voltage or less; and
correct the depth of discharge based on the identified time.

9. A method of diagnosing battery discharge, the method comprising:
obtaining a voltage of a battery unit;
calculating a weighted sum value of a number of times the voltage of the battery unit is sensed in a plurality of different voltage ranges; and
diagnosing a depth of discharge of the battery unit by comparing the weighted sum value with at least one threshold value.

10. The method of claim 9, wherein calculating the weighted sum value comprises determining a sum of products of the number of times the voltage of the battery unit is sensed in the plurality of different voltage ranges and a plurality of weight values corresponding to the plurality of voltage ranges.

11. The method of claim 10,
wherein the plurality of weight values includes a first weight value corresponding to a voltage range; and
wherein the first weight value corresponding to the voltage range is set to be lower for a higher upper limit of the voltage range.

12. The method of claim 9, further comprising:
obtaining first voltage values of a plurality of new battery units having use periods being less than or equal to a first reference period and second voltage values of a plurality of old battery units having use periods being greater than a second reference period; and
determining the plurality of voltage ranges based on the first voltage values and the second voltage values.

13. The method of claim 12, wherein determining the plurality of voltage ranges comprises:
determining a first voltage range having a maximum value of the first voltage values as an upper limit and a minimum value of the first voltage values as a lower limit;
determining a second voltage range having a maximum value of the second voltage values as an upper limit and a minimum value of the second voltage values as a lower limit;
determining a target voltage range by excluding the first voltage range from the second voltage range; and
determining the plurality of voltage ranges in the target voltage range.

14. The method of claim 13, wherein determining the plurality of voltage ranges comprises is based on a distribution of the second voltage values in the target voltage range.

15. The method of claim 9, further comprising:
obtaining a number of times the battery unit is charged by a second battery unit disposed in an electronic device when the electronic device is in a powered-off state; and
correcting the depth of discharge based on the number of times the battery unit is charged by the second battery unit.
